(19) United States
(12) Patent Application Publication
(10) Pub. No.: US 2007/0085096 A1
(43) Pub. Date: Apr. 19, 2007

(54) Light emitting diode package

(75) Inventor: Bo Geun Park, Gwangju (KR)

Correspondence Address: BIRCH STEWART KOLASCH & BIRCH, PO BOX 747, FALLS CHURCH, VA, 22040-0747, US

(73) Assignee: LG INNOTEK CO., LTD

(21) Appl. No.: 11/546,322

(22) Filed: Oct. 12, 2006

(30) Foreign Application Priority Data
Oct. 13, 2005 (KR) 10-2005-0096311

(51) Int. Cl. H01L 33/00

(52) U.S. Cl. 257/94

(57) ABSTRACT

An LED package is provided. The LED package includes: at least one device having at least one LED; at least one resistor having a resistance component; a plurality of bonding pads formed spaced apart from each other on one side of the resistor and changing resistance of the resistor according to a wire bonding position; a conductive part having a current flowing path to electrically connect the device and the resistor; and a substrate having the device, the resistor, and the conductive part.

### BACKGROUND OF THE INVENTION

1. Field of the Invention

The present invention relates to a light emitting diode (LED) package.

2. Description of the Related Art

An LED is a device that converts electrical signals into infrared rays, visible rays, or ultraviolet rays to transmit and receive signals using compound semiconductor characteristics.

A related art LED is widely used in mobile communication terminals, electrical appliances, remote controllers, display panels, indicators, and various automation devices. Additionally, the related art LED is classified into an infra-red emitting diode (IRED) type and a visible light emitting diode (VLED) type.

The LED requires a low driving voltage to be used as a backlight in an industrial field of the mobile communication terminals such as a smart phone, a mobile phone, and a personal digital assistant (PDA). Additionally, The LED requires high-brightness property to be used in outdoor systems.

Because of this reason, white light LED development has been more actively progressed. Advantages of the white light LED are low-power consumption, compatibility with related art LCD products, low heat generation for preventing the function deterioration of an LCD panel, a light source for a wide view angle in various environments, low cost, and excellent durability.

In the white light LED, a red LED, a green LED, and a blue LED constitute one package, and are mounted on a metal substrate having a heat dissipation function. A manufacturing method includes a method filling a container having a cup-shape reflecting plate with mold, and a method using a transfer mold process, that is, a semiconductor package mold process.

FIG. 1 is a plan view of a related art LED package. FIG. 2 is a side view of a related art LED package.

Referring to FIGS. 1 and 2, an LED device 30 is mounted on a metal substrate 10, and a current flowing path 20 is formed on the metal substrate 10. Moreover, a wire 40 connects the current flowing path 20 and the LED device 30 in a bonding form.

Although the LED device 30 is originally manufactured with the same degree of light intensity, the light intensity is changed through various processes, and color deviation occurs according to the change of the light intensity. Especially, the light intensity of one color LED in three color LEDs constituting white light deteriorates such that it makes very difficult to embody a desirable color.

When the light intensity and color deviation occur, a fixed resistor is inserted into the related art LED package to control color deviation, or the LED device itself is replaced. However, since the metal substrate 10 has excellent heat conductivity, soldering needs to be done rapidly to connect a fixed resistor. A soldering process is troublesome, and has a problem of risking other devices with an adverse effect. Additionally, replacing of the LED device itself makes a manufacturing process more complex and inefficient. In an aspect of expenses, it imposes a heavy burden on a manufacturing process.

Under these circumstances, a new technique is in demand, which can effectively control the color deviation of an LED package by improving a process that inserts a resistor on a substrate.

### SUMMARY OF THE INVENTION

The present invention provides provide an LED package capable of controlling the uniform light intensity between LEDs.

The present invention provides provide an LED package capable of realizing desirable colors by easily adjusting color deviation when a post process is performed on a specific LED having color deviation.

The embodiment of the present invention provides an LED package including: at least one device having at least one LED; at least one resistor having a resistance component; a plurality of bonding pads formed spaced apart from each other on one side of the resistor and changing resistance of the resistor according to a wire bonding position; a conductive part having a current flowing path to electrically connect the device and the resistor; and a substrate having the device, the resistor, and the conductive part.

The embodiment of the present invention provides an LED package including: a substrate; a conductive part formed on the substrate; at least one device emitting light using a voltage supplied from the conductive part; at least one LED provided to the device; at least one resistor connected to the device electrically; a plurality of bonding pads spaced apart from each other and provided to the resistor; and a wire bonding part connecting the bonding pads each other to control resistance of the resistor.

The embodiment of the present invention provides An LED (light emitting diode) package including: a substrate; a conductive part formed on the substrate; at least one device emitting light using a voltage supplied from the conductive part; at least one LED provided to the device; at least one resistor disposed in a line form and connected to the device electrically; a plurality of bonding pads provided to the resistor; and a wire bonding part connecting the bonding pads each other and controlling a length of the resistor to serve as an actual resistance.

### BRIEF DESCRIPTION OF THE DRAWINGS

FIG. 1 is a plan view of a related art LED package;

FIG. 2 is a side view of a related art LED package;

FIG. 3 is a plan view of an LED package according to an embodiment of the present invention;

FIG. 4 is a sectional view of a device structure according to an embodiment of the present invention;

FIG. 5 is a view of a resistor and a device connected in parallel of an LED package according to an embodiment of the present invention; and

FIG. 6 is a side view of an LED package having a resistor according to an embodiment of the present invention.

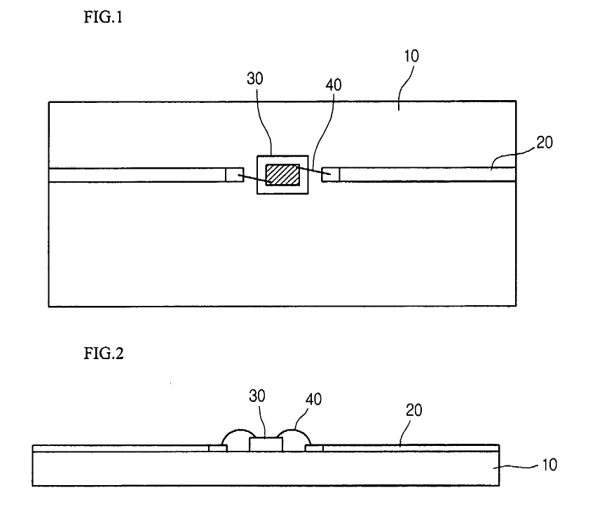

### DETAILED DESCRIPTION OF THE INVENTION

Reference will now be made in detail to the preferred embodiments of the present invention, examples of which are illustrated in the accompanying drawings.

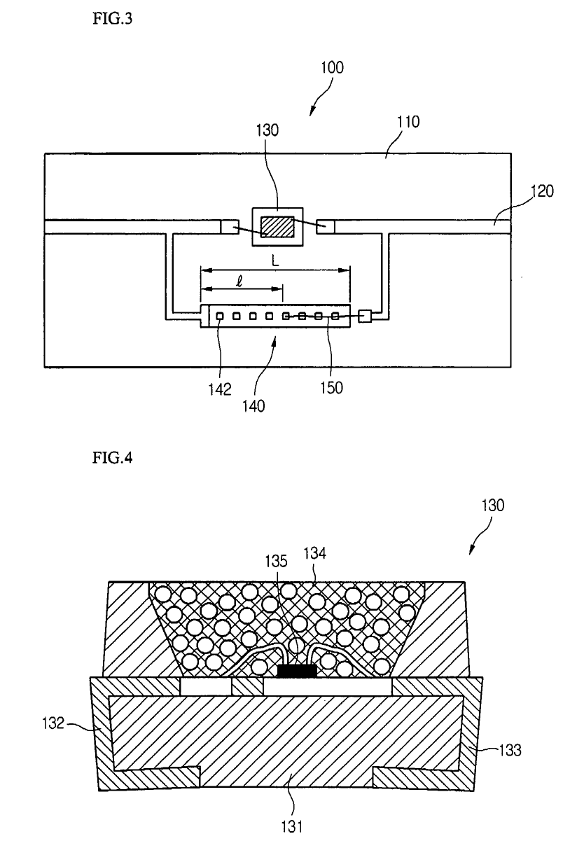

FIG. 3 is a plan view of an LED package 100 according to an embodiment of the present invention.

Referring to FIG. 3, the LED package 100 includes a substrate 110, a device 130, a resistor(s) 140, a conductive part 120, and a wire bonding part 150.

First, a structure of the device 130 will be described with reference to FIG. 4.

The device 130 includes an injection molded plastic structure 131, a first metal post (anode lead) 132, a second metal post (cathode lead) 133, a resin mold 134, and an LED chip 135.

A red LED chip, a green LED, and a blue LED can be independently used as the LED chip 135. In this case, the light intensity of a single LED chip can be controlled by the resistor 140. In another case, various colors can be realized by using devices 130 having the different color LED chips, respectively. In this case, the light intensity between the devices 130 can be controlled by the resistors 140. However, in the embodiment, one device and one resistor are illustrated in FIG. 3 for convenience.

Referring to FIG. 3, the resistor 140 is disposed in parallel to the device 130 on the substrate 110 and is strip-shaped, that is, linear generally. Additionally, the resistor 140 does not need to be disposed in parallel to the device 130, and can be in any forms as long as it is linear. However, it is desirable for the resistor 140 to be disposed adjacent to the device 130 such that the resistor 140 controlling the light intensity and the color deviation of the device 130 can be more easily distinguished.

More specifically, the resistor 140 can be formed by adhering or depositing carbon resistance such as oxide material and dielectric material to the substrate 110. A plurality of bonding pads 142 spaced a predetermined distance apart from each other are deposited on the substrate 110 in a structure of the resistor 140. Accordingly, when certain bonding pads are selected to conduct a current, the resistor 140 has a different number of a resistance component according to the position of the bonding pad 142. For example, the length of the resistor 140 is shortened by the conducted length of the bonding pad 142 such that resistance decreases. As well-known, since electrical conductivity of material constituting the bonding pad 142 and the wire is higher than that of material constituting the resistor 140, most of the current flows through the wire from the position where the bonding pad 142 and the wire are connected. Thus, the length l of the resistor 140 becomes shortened compared to a total length L such that resistance decreases. Furthermore, as the number of the bonding pads 142 increases, a resistance component having an excellent changeability can be provided.

Here, a process for forming the resistor 140 may be performed together with a process for forming the device 130.

Additionally, as illustrated in FIG. 3, the resistor 140 is strip-shaped, but can be formed adjacent to the device 130 with a jig-jag shape according to the arrangement with respect to other devices, or a ring-shape surrounding the device 130.

The bonding pad 142 in the resistor 140 may be plated with gold because gold has a chemical stability and high electrical conductivity such that reliability of contact portion increases.

Next, the conductive part 120 is wire-bonded with the electrode on the device 130 to provide a current flowing path for a voltage. The conductive part 120 is diverged to extend toward both sides of the device 130 and the resistor 140. At least one in conductive parts 120, which is adjacent to the both sides of the resistor 140, does not contact the resistor 140 and is spaced apart from the resistor 140. The conductive part 120 that does not contact the resistor 140 is wire-bonded with the resistor 140 in order that the resistor 140 and the device 130 areo in a parallel structure with respect to the conductive part 120.

Additionally, when one end of the resistor 140 is formed on the conductive part 120, the convenience for the manufacturing processes increases.

Processes for fabricating the LED of the present invention will be described with reference to FIG. 3.

First, the conductive part 120 is formed on the substrate 110. Next, the device 130 and the resistor 140 are mounted on the substrate 110. Bonding processes of the device 130 and the resistor 140 with the conductive part 120 are performed. Then, after identifying light intensity and color deviation in light emitted on the device 130, a boding process between the resistor 140 and the bonding pad 142 is performed. At this point, the resistance generated by the resistor 140 can be controlled such that an amount of a current flowing into the device 130 can be adjusted. Furthermore, the light intensity and the color deviation of the device 130 can be easily adjusted.

On the other hand, the device 130, the resistor 140, and the conductive part 120 are mounted on the surface of the substrate 110. A metal core printed circuit board (MCPCB) is generally used as the substrate 110. Since the MCPCB has excellent heat conductivity, the heat generated from the device 130 is effectively dissipated into the outside such that operational reliability of the LED package can improve. On the other hand, when soldering is additionally performed as the related art, the heat is delivered into the device 130 such that bad effects occur. However, the resistor 140 of the present invention does not use the direct soldering method in the related art, and a wire bonding process is performed in a subsequent process such that problems of heat conducting through the substrate 110 do not occur. Furthermore, since the small heat generated during the wire bonding process is absorbed in the resistor 140 first, the heat conducting into the substrate 110 more drastically decreases. Moreover, since the resistor 140 is non-conductor for heat, the heat generated during the wire bonding process is more reliably blocked from being delivered into the substrate 110.

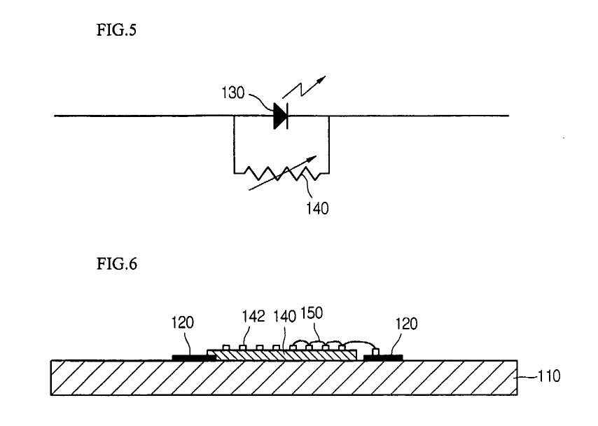

FIG. 5 is a view of the resistor 140 and the device 130 connected in parallel of an LED package according to an embodiment of the present invention. Referring to FIG. 5, since the resistor 140 serves as a variable resistor, an amount of a current flowing into the device 130 can be easily adjusted.

FIG. 6 is a side view of an LED package having a resistor according to an embodiment of the present invention.

Referring to FIG. 6, a plurality of bonding pads 142 are deposited in a row on the resistor 140. Four bonding pads 142 on the right side of the drawing are mutually wire-bonded. Also, first bonding pad of four bonding pads 142 and the end of the conductive part 120 may be wire-bonded.

At this point, the wire bonding is processed with a gold line. When controlling the light intensity between the devices 130, the bonding method can be different according to the convenience of the controlling of the light intensity.

For example, the bonding pads 142 can be bonded one by one when measuring the light intensity of the device 130, or can be cut one by one according to the measuring result of the light intensity in the device 130 after bonding the bonding pads 142. In another method, when the degree of the resistance is known, without being connected to the middle bonding pad 142, the bonding pad 142 in the predetermined position is directly and electrically connected to the conductive part 120.

Another case in the present invention, the device 130 and the resistor 140 are connected in parallel in the present invention, the present invention is not limited to this. The device 130 and the resistor 140 can be connected in series, and also this can be applied to the present invention.

According to the LED package of the present invention, since the resistor is soldered after the device is mounted on the substrate, heat conductive effect due to the soldering of the resistor can be minimized. Additionally, since the LED device itself does not need to be replaced, processes become simplified and a failure rate of the product decreases.

Additionally, according to the present invention, the number of the bonding pads is selected to provide a variable resistance value such that manufacturing time drastically decreases. Since color deviation adjustment can be simply processed, the light intensity deviation between LEDs can be easily adjusted.

What is claimed is:

1. An LED (light emitting diode) package comprising:
at least one device having at least one LED;
at least one resistor having a resistance component;
a plurality of bonding pads spaced apart from each other on one side of the resistor and changing resistance of the resistor according to a wire bonding position;
a conductive part having a current flowing path to electrically connect the device to the resistor; and
a substrate on which the device, the resistor, and the conductive part are formed.

2. The LED package according to claim 1, wherein the LED comprises at least one of a red LED, a green LED, and a blue LED.

3. The LED package according to claim 1, wherein the resistor is in a line form.

4. The LED package according to claim 1, wherein the resistor is in a band form in one of a straight line form, a jig-jag form, and a ring form, and is formed adjacent to the device.

5. The LED package according to claim 1, wherein the bonding pad comprises gold.

6. The LED package according to claim 1, wherein the device and the resistor are connected in a parallel circuit or a serial circuit using the conductive part.

7. The LED package according to claim 1, wherein the substrate is a MCPCB (metal core printed circuit board).

8. The LED package according to claim 1, wherein the resistor comprises one of an oxide resistance and a dielectric resistance.

9. An LED (light emitting diode) package comprising:
a substrate;
a conductive part formed on the substrate;
at least device emitting light using a voltage supplied from the conductive part;
at least one LED provided to the device;
at least one resistor electrically connected to the device;
a plurality of bonding pads spaced apart from each other and provided to the resistor; and
a wire bonding part connecting the bonding pads to each other to control resistance of the resistor.

10. The LED package according to claim 9, wherein the resistor is in a line form.

11. The LED package according to claim 9, wherein the controlling of the resistance of the resistor using the wire bonding part comprises one of cutting the already-connected wire bonding part, connecting the adjacent bonding pads with the wire bonding part, and directly connecting the respectively spaced bonding pads.

12. The LED package according to claim 9, wherein the resistor is adjacent to the device.

13. The LED package according to claim 9, wherein the resistor is mounted on the surface of the substrate.

14. The LED package according to claim 9, wherein at least one end in both ends of the resistor is permanently connected to the conductive part.

15. The LED package according to claim 9, wherein the device and the resistor are connected in series or in parallel.

16. The LED package according to claim 9, wherein one bonding pad of the resistor and one end of the conductive part are connected by the wire bonding part.

17. The LED package according to claim 9, wherein a red LED, a green LED, and a blue LED are mounted on the device.

18. An LED (light emitting diode) package comprising:
a substrate;
a conductive part formed on the substrate;
at least one device emitting light using a voltage supplied from the conductive part;
at least one LED provided to the device;
at least one resistor disposed in a line form and electrically connected to the device;
a plurality of bonding pads provided to the resistor; and
a wire bonding part connecting the bonding pads to each other and controlling a length of the resistor serving as an actual resistance.

19. The LED package according to claim 18, wherein the resistor is formed of a non-conductive material for heat.

20. The LED package according to claim 18, wherein the boding pad is provided on the resistor and spaced a predetermined distance apart from each other.
